(19) United States
(12) Patent Application Publication
(10) Pub. No.: US 2009/0248334 A1
(43) Pub. Date: Oct. 1, 2009

(54) METHOD FOR ESTIMATING THE CHARGE OF A MOTOR VEHICLE BATTERY

(75) Inventors: Mariano SANS, Blagnac (FR); Pierre-Antoine BAFFAUT, Toulouse (FR); Paul Boucharel, Toulouse (FR)

Correspondence Address: YOUNG & THOMPSON, 209 Madison Street, Suite 500, ALEXANDRIA, VA, 22314, US

(73) Assignee: CONTINENTAL AUTOMOTIVE FRANCE, Toulouse (FR)

(21) Appl. No.: 12/411,819

(22) Filed: Mar. 26, 2009

(30) Foreign Application Priority Data
Mar. 27, 2008 (FR) 0801664

(51) Int. Cl. G01R 31/36; G01N 27/416

(52) U.S. Cl. 702/63; 324/431

(57) ABSTRACT

In a method for estimating the charge of a motor vehicle battery, at least one sensor measures terminal voltage, current circulating in the battery, and temperature, such that: current variations are measured at predetermined time intervals; a modeled voltage is determined according to current and temperature; the modeled voltage includes components corresponding to charge polarization; estimated and measured voltage are compared to determine voltage error; theoretical model is adapted according to battery operating phase and determined voltage error. Operating phases of the battery on charge and discharge correspond on each occasion to operation substates including 100% saturated, close to 100% saturated, normal, close to 0% charged and 0% charged and in that, for the substates, adaptation is made for theoretical computation of battery charge state and/or computation of the component corresponding to polarization, the estimate of the state of charge of the battery being determined using the adapted theoretical model.

The present invention relates to a method for estimating the charge of a motor vehicle battery.

To determine the state of a battery in a motor vehicle, two types of parameters are usually used. First of all the state of charge is used which indicates, as a percentage, the charge of the battery relative to its maximum charge. This state of charge must be able to be determined irrespective of the battery type used in the motor vehicle. The state of health of the battery is also used which depends on various internal parameters of the battery such as, in particular, the internal resistance of the battery, the maximum charge capacity of this battery and the acceptance of charge which corresponds to the voltage beyond which charging of the battery is no longer effective.

The present invention relates more particularly to the state of charge of a battery. This state of charge is defined according to the predefined normal conditions of use which correspond to standards which may vary from one country to another.

In order to determine the state of charge of a battery, it is possible to measure the voltage when empty (open circuit) at the battery terminals by taking a highly precise measurement in order to determine the density of the acid present in the battery. This measurement method can be carried out only after a long period of rest for the battery. At low temperatures, the rest time necessary after a charging phase may be very long, for example of the order of several days. This determination method is therefore not able to be used for a real-time estimate.

It is also possible to envisage measuring the charge variations of the battery by integrating into the time the current circulating in said battery beginning at a known starting point and knowing the estimated maximum capacity of the battery. The user then manages to compute the state of charge of the battery as a percentage of the maximum charge. However, because of errors of measurement of the current, the integrated value may have relatively major variations relative to the variation of real charge of the battery.

A priori, no direct method of measuring the state of charge is possible during the phases of use of a battery without providing an additional sensor or sensors on the battery (so as, for example, to take a measurement of the density of the acid that is in the battery).

The object of the present invention is therefore to provide a method making it possible to estimate the state of charge of a battery in a motor vehicle. This method will preferably allow usage in real time and will be able to be implemented in a cheap onboard computer. Another object of the invention is for this estimate to take account of the main physical phenomena that occur inside a battery. The method must be sufficiently complex to provide a reliable, but not too complex, indication to facilitate its implementation.

Another object of the present invention is to simulate the short-term or medium-term behavior of a battery in order to make it possible to predict the capability of the battery to supply sufficient energy for a given task (for example cold starting, stopping and starting the engine, also called “stop & go”, etc.).

Accordingly, the present invention proposes a method for estimating the charge of a motor vehicle battery in which at least one sensor supplies the voltage at the battery terminals, the current circulating in the battery and the temperature of the latter.

According to the present invention, current variations are measured at predetermined time intervals in order to determine by integration variations of charge of the battery,
a modeled voltage is determined according to the current and the temperature with the aid of a theoretical model,
the modeled voltage comprises at least one component corresponding to the charge of the battery and at least one component corresponding to the polarization of the battery,
the estimated voltage is compared with the measured voltage in order to determine a voltage error,
an adaptation of the theoretical model is made according to the operating phase of the battery and according to the determined voltage error, and
the adaptation is made for the theoretical computation of the state of charge of the battery and/or for the computation of the component corresponding to the polarization of the battery,
the estimate of the state of charge of the battery being determined with the aid of the adapted theoretical model.

Such a method therefore makes it possible to respond to the technical problem explained above by estimating the state of charge of a battery at all times. Thanks to the adaptations made, the same method may be used on several batteries and also adapts to the aging of a battery.

In an estimation method according to the invention, the current variation measurements are made at a frequency greater than 1 Hz. It is possible, for example, to provide measurements made every 10 ms or every 100 ms, for example.

The various operating states of the battery which are considered in the method according to the invention may be chosen from the set comprising operation in open circuit, operation on charge and operation on discharge.

It is also possible preferably to provide that the operating states of the battery on charge and on discharge correspond on each occasion to operating substates chosen from the set comprising 100% saturated operation, close to 100% saturated operation, normal operation, close to 0% charged operation and 0% charged operation.

For these various substates, it is proposed that, in the 100% saturated operation substate, the adaptation is made on the state of charge of the battery and on the component corresponding to the polarization of the battery, that, in the close to 100% saturated operation substate, the adaptation is made on the component corresponding to the polarization of the battery, that, in the normal operation substate, the adaptation is made on the state of charge of the battery and on the component corresponding to the polarization of the battery, that, in the close to 0% charged operation substate, the adaptation is made on the component corresponding to the polarization of the battery, and that, in the 0% charged operation substate, the adaptation is made on the state of charge of the battery and on the component corresponding to the polarization of the battery.

It should be noted that the speed of adaptation of the state of charge and the speed of adaptation of the polarization depend (independently of one another) on the operating states of the battery.

It is also possible to provide that, the state of operation of the battery in open circuit corresponds to operation substates chosen from the set comprising 100% saturated operation, close to 100% saturated operation, close to 0% charged operation, 0% charged operation, operation with a stable voltage, operation with an unstable voltage and operation in open circuit with a long stability.

For these various substates, it is proposed that, in the 100% saturated operation, close to 100% saturated operation, close to 0% charged operation and 0% charged operation substates, the adaptation is made on the state of charge of the battery and on the component corresponding to the polarization of the battery, that, in the operating state with a stable voltage, the adaptation is made on the state of charge of the battery and on the component corresponding to the polarization of the battery with a preponderant adaptation on the state of charge, that, in the state of operation with an unstable voltage, the adaptation is made on the state of charge of the battery and on the component corresponding to the polarization of the battery with a preponderant adaptation on the component corresponding to the polarization, and that, in the state of operation in open circuit with a long stability, the adaptation is made only on the state of charge of the battery.

In an estimation method according to the invention, in order to help determine the various operating states and the possible operating substates, a timer may be used when the battery operates in open circuit in order to measure the time elapsed since the opening of the circuit.

The present invention also relates to a computer program stored on a data medium, said program comprising instructions allowing the use of an estimation method as described above, when this program is loaded and run by an information technology system.

Finally, this invention relates to an information technology system such as, for example, a computer designed to be installed on board a motor vehicle, characterized in that it comprises means appropriate for applying an estimation method as described above.

Details and advantages of the present invention will better emerge from the following description made with reference to the appended schematic drawing in which:

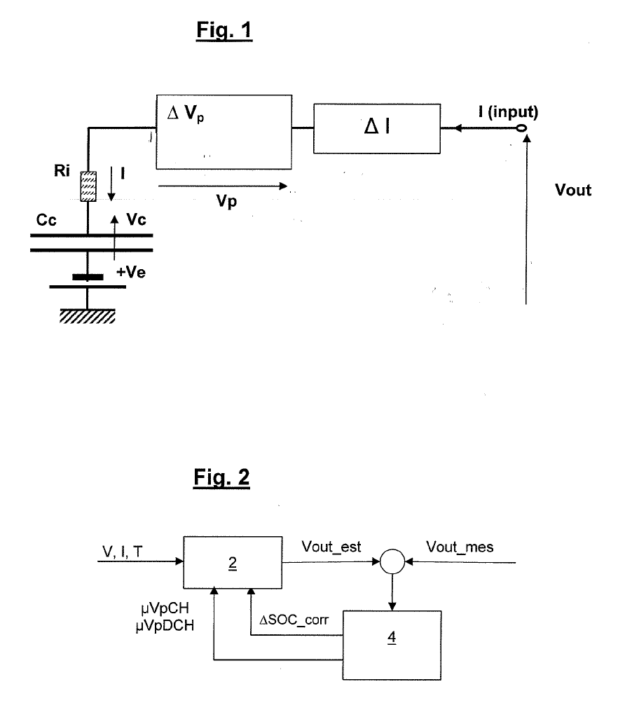

FIG. 1 is a diagram for modeling a battery used in the present invention, and

FIG. 2 illustrates a method according to the present invention.

FIG. 1 shows various elements taken into account in the present invention to make an estimate of the charge of a battery. This battery shown in FIG. 1 comprises first of all an element at the terminals of which there is a voltage Ve. The latter is usually 11.5 V. Above this element, at the terminals of which there is a constant potential difference, there is in FIG. 1 a capacitor called Cc which makes it possible to “store” the energy contained in the battery. When this capacitor is fully charged, the voltage Vc at its terminals is approximately 1.3 V.

The various elements forming the battery have a resistance combined in this instance into a single resistor called Ri. According to Ohm's law, a voltage appears at the terminals of this resistor when the latter is traversed by a current I.

In a known manner, when a battery is used, a polarization voltage, here called Vp, appears. This voltage is positive when the battery is on charge and negative when the battery discharges. This polarization voltage Vp results from the current circulating in the battery and from the temperature of the latter. This polarization comprises both a static component and a dynamic component. The static component of the battery is called Gp and it is assumed that this value depends on the current I circulating in the battery, on the charge (SOC) and on the temperature T of the battery, that is to say Gp (I, SOC, T).

The dynamic component of the polarization voltage corresponds to a first-order damping of this voltage over time. This damping is carried out with a time constant τp. This time constant varies according to the state of the battery. It is therefore lower during a discharge phase than in a charging phase. This time constant, in open circuit, has a higher value than in a closed circuit phase. Also in a known manner, this time constant is greater when cold than when hot.

Therefore, for example, ΔVp=Gp(I, SOC, T)/(1+τp (I).S).

Finally, there is also in a battery a loss of current symbolized in FIG. 1 by ΔI and sometimes designated as the “gassing effect”.

In steady state, when no current is circulating in the battery and all the polarization effects have disappeared (it is sometimes necessary to wait a few days), the apparent voltage Vout at the battery terminals corresponds to Ve+Vc.

In transitory state, on charge, on discharge or in open circuit, the following should be taken into account:
the effective current, taking account of the current loss (gassing effect),
the value of the voltage Vc which depends on the load of the capacitor Cc,
the voltage loss associated with the internal resistance Ri of the battery,
the polarization voltage Vp associated with the current, the time and the temperature, and
the voltage at the battery terminals being the sum of the voltages mentioned above.

The state of charge of the battery is called SOC. It corresponds to the ratio between the actual charge of the battery and its maximum charge. This therefore gives:

SOC [%]=Q/Qmax.

A usual way of measuring this state of charge is to fully discharge the battery until the voltage at the battery terminals falls in order to measure the remaining charge Q (in Ah), then to fully recharge the battery and fully discharge it again in order to determine the maximum charge Qmax. The state of charge SOC is then the ratio between the charge Q and the charge Qmax which are measured.

As it is possible to note, this test is lengthy to run, and it is also an intrusive test which changes the initial state of the battery which must be measured.

It is also noteworthy that the measured value Qmax depends on the way in which the battery is discharged. This is the result in particular of Peukert's law. Various protocols are used to discharge the battery. The latter may be carried out for example in five hours (used notably as the standard in Japan), in twenty hours (usually used as the standard in Europe) or else in one hundred hours (for the batteries of electric vehicles). It will be assumed, for example, that the maximum charge Qmax used in this instance corresponds, in the rest of the description, to the maximum charge measured when the battery is discharged in twenty hours. Naturally, this definition of Qmax does not influence the present invention.

For the application of the invention, sensors on the battery measure the current, the voltage and the temperature.

At regular intervals, measurements are taken and based on these measurements current variations and voltage variations are computed. These measurements are, for example, taken every 10 ms or 100 ms.

In the method for estimating the charge of the battery (SOC) according to the present invention, the parameters (current, voltage, temperature) of the battery are observed and it is seen how the latter reacts. In parallel, a model estimates, according to the parameters and their variations, how the battery should react. This model is automatically adapted according to the battery reactions which are measured.

The model used for the battery is described above. The computations making it possible to estimate the voltage at the battery terminals in order to determine the state of charge of the latter are given in detail below.

First of all, it is necessary to determine the effective current to be taken into account. This current corresponds to the total current from which the current loss ΔI is deducted. This current loss is computed on the basis of the temperature and the voltage. The current loss may be computed by a formula or else be determined by consulting a table. This current loss increases with the temperature and also increases with the voltage.

To compute the voltage Vc, two computation modes may be adopted. It is possible either to carry out a linear integration, or to carry out a nonlinear integration.

Carrying out a linear integration begins with the following equation:

Vcₙ=Vcₙ₋₁+ΔA.h/Qmax [Ah]*Vcmax

In this equation, Vcₙ is the new value of the voltage Vc to be determined while Vcₙ₋₁ is the old determined value of Vc.

In this equation, ΔA.h corresponds to a charge variation and is computed by multiplying the value of the current (corrected) by the duration of the sampling period. This gives:

SOC=Vc/Vcmax [%]

Where Vcmax=1.3 V usually.

It is however preferable to carry out a nonlinear integration. Here, the new state of charge is determined as a function of the old one according to the following equation:

SOCₙ=SOCₙ₋₁+ΔA.h/Qmax [Ah]*100 [%]

The voltage Vc is then determined on the basis of the state of charge SOC.

To compute the voltage at the terminals of Ri, it is assumed that the value of this resistance is known and the voltage is then computed using Ohm's law.

As already indicated above, the polarization voltage has a static component and a dynamic component. Since the behavior of this dynamic component is different on charge or on discharge of the battery, it is proposed to cut the voltage signal Vp into two separate signals, a positive signal incorporating the effects which are due to the charge and a negative signal reflecting the effects which are due to the discharge. This then gives the following equations:

Vp=Vp(CH)+Vp(DCH)

where Vp(CH)=VPstat(CH)*Vp dyn(Ch)>0

and Vp(DCH)=VPstat(DCH)*Vp dyn(DCH)<0

where Vp(CH) corresponds to the polarization voltage on charge and Vp(DCH) corresponds to the polarization voltage during a discharge.

Finally, the following equation is obtained for the voltage at the battery terminals:

Vout=Ve+Vc+Ri*I+Vp

This voltage, computed as indicated above, corresponds to the modeled voltage representing the response of the battery to a given current. Like all modeling, the latter has errors which must be corrected. It is proposed in this instance to make an adaptation of the model.

Several adaptations may be made and combined to obtain an overall correct correction. The adaptation is made according to the phase in which the battery is. It is possible therefore to provide an adaptation when the battery is in open circuit, an adaptation acting on the polarization model of the battery and adaptations when the state of charge of the battery is close to 0% or 100%.

When the battery is in open circuit, the voltage at its terminals Vout tends fairly precisely toward its open circuit voltage OCV.

The estimate made of the state of charge SOC may then be corrected in order to become equal to the corresponding value of the open circuit voltage OCV by an operation of closed loop integration of the error between the actual value of the state of charge and the value of the state of charge equivalent to the open circuit voltage OCV. When the steady state is achieved, the two values must be equal (and dependent on the temperature). The gains of this operation depend on the damping of the polarization voltage and on the temperature: the more the polarization is damped, the better are the gains and the lower the temperature, the lower are the gains.

The corrective term may take the following form:

ΔSOC_corr=Kp*SOC_error+Ki*∫SOC_error. dt

In which

SOC_error=SOC_OCV−SOC_est

This then gives

SOCₙ=SOCₙ₋₁+ΔSOC_corr

A timer is for example used as soon as a battery charging phase or discharging phase is completed. It is possible to provide that this timer is activated when the value of the current passes below a predetermined threshold, this threshold naturally being relatively low. The correction of the state of charge is then made when the timer has been activated for a relatively long time, for example several hours. The user then makes the estimate of the state of charge SOC converge with the value SOC_OCV which is the state of charge corresponding to the open circuit voltage of the battery. The gains Kp and Ki mentioned in the above equation depend on the time value indicated by the timer. It is possible if necessary to provide that Ki=0.

It is also possible to make an extrapolation on the one hand of the voltage since the battery is in open circuit and on the other hand of the estimate of the state of charge. If the extrapolation made of the state of charge does not correspond to the value of the state of charge corresponding to the extrapolated open circuit voltage OCV, a correction must then be made.

Parallel with the adaptations made in open circuit, an adaptation relating to the polarization may be made both during a charging phase and during a discharging phase or in open circuit.

The polarization model is representative of the nonlinear impedances of the circuit as described above. The behavior of this polarization may vary widely from one battery to another and a auto-adaptation is therefore necessary in this case.

To make this adaptation relating to the polarization of a battery, the measured output voltage is compared permanently with the computed output voltage. A correction is permanently made according to the difference between the measured voltage and the computed voltage in order to compensate for the error on the polarization voltage and/or the charge voltage (at the capacitor terminals) or the internal voltage in open circuit.

When the state of charge SOC is assumed to be most reliable, the adaptation is made by applying a corrective term to the polarization voltage. In this instance a correction factor ηVp is used. In a preferred embodiment, a correction factor μVpCH is used after a battery charge while a factor μVpDCH is applied after a discharging phase. On the other hand, when the computed polarization voltage is assumed to be reliable, the adaptation is made on the estimate of the state of charge SOC and the corrective factor already mentioned above, ΔSOC_corr, is then used.

FIG. 2 illustrates the estimation method according to the invention using adaptations both on the state of charge and on the polarization voltage.

In FIG. 2, the reference 2 represents the modeling of the battery while reference 4 represents the auto-adaptation means.

As emerges from the description given above, sensors measure the voltage V, the current I and the temperature T of the battery. These data are injected into the modeling of the battery 2 in order to supply an estimated voltage Vout_est. Furthermore, this voltage Vout is measured and has the value Vout_mes. The two values are compared and the result of this comparison is inserted into the auto-adaptation means 4. The latter then supply corrective terms ΔSOC_corr and μVpCH and μVpDCH.

The strategy of combining the state of charge correction and the polarization voltage is managed according to a schematic diagram taking account of the current, the voltage and the temperature and the history of the corrections made.

An indicator of confidence concerning the polarization voltage may be used. This indicator will be high after a long phase in open circuit or after a long phase during which the current is substantially constant. On the other hand, confidence in the polarization voltage will be low during transition phases or after a significant current variation.

Adaptations on the value of the state of charge will therefore be made when the indicator of confidence on the polarization value is high.

Other adaptations may also be made. Specifically, the system may automatically detect some typical situations, notably when the state of charge is close to 0% or close to 100%. During a discharging phase, when the state of charge reaches the limit of 0%, the output voltage decreases suddenly and very rapidly. This situation may be easily detected by measuring the voltage gradient.

Therefore, for example, if Vout decreases until it reaches a value of less than 10.5 V with a substantial negative gradient, or if a charging current reaches a very high value but with a value Vout that is relatively low, for example less than 13.5 V, then the estimate of the state of charge SOC of the battery is corrected to converge with the lower limit of 0% corresponding to the measured temperature. If the state of charge is still positive, then the estimated state of charge is reduced to 0%. On the other hand, if the estimated state of charge has already reached 0% and tends to be negative, then the state of charge is maintained at 0%.

In a similar manner, it is possible to detect a state of charge close to 100% during a battery charging phase. The output voltage then increases rapidly and suddenly, so that the state of charge close to 100% may be easily detected by measuring the voltage gradient.

Therefore, for example, if Vout increases and exceeds 16.5 V, with a major voltage gradient or if the charging current reaches 0 A with a substantially stabilized voltage at a relatively high value, for example greater than 14 V, then the estimate of the state of charge SOC is corrected in order to converge with the value of 100%. If the estimated state of charge is still below 100%, then this state of charge is increased to reach the value of 100%. On the other hand, if the estimated state of charge has already reached 100% and tends to become greater than 100%, then the estimated state of charge is maintained at 100%.

The method described above thus makes it possible to obtain a good estimate of the charging state of a battery. During a first use, for example after a battery change, a period of adaptation is most frequently necessary. The method described above, thanks notably to the adaptation of the polarization voltage, makes it possible to obtain fairly rapidly a good estimate of the state of charge.

The method according to the invention allows an estimate of the charge of the battery during all the phases of use of the latter. The estimated value is readjusted permanently by comparison between a modeled voltage and a measured voltage. This makes it possible to have a reliable estimate of the state of charge of the battery throughout the lifetime of the battery, even when the latter ages.

As emerges from the above description, the present invention is an application of several auto-adaptation methods, by prediction or by extrapolation, with the use of a real-time correction in closed loop suitable for the operating phases.

The present invention is not limited to the embodiment described above or to the variant embodiments mentioned. It also relates to all the variant embodiments within the scope of those skilled in the art in the context of the following claims.

1. Method for estimating the charge of a motor vehicle battery in which at least one sensor supplies the voltage at the battery terminals, the current circulating in the battery and the temperature of the latter, such that:
current variations are measured at predetermined time intervals in order to determine by integration variations of load of the battery,
a modeled voltage is determined according to the current and the temperature with the aid of a theoretical model,
the modeled voltage comprises at least one component corresponding to the charge of the battery and at least one component corresponding to the polarization of the battery,
the estimated voltage is compared with the measured voltage in order to determine a voltage error,
an adaptation of the theoretical model is made according to the operating phase of the battery comprising operation on open circuit, operation on charge and operation on discharge and according to the determined voltage error,
the method being characterized in that the operating phases of the battery on charge and on discharge correspond on each occasion to operation substates chosen from the set comprising 100% saturated operation, close to 100% saturated operation, normal operation, close to 0% charged operation and 0% charged operation and in that, for these various substates, the adaptation is made for the theoretical computation of the state of charge of the battery and/or for the computation of the component corresponding to the polarization of the battery, the estimate of the state of charge of the battery being determined with the aid of the adapted theoretical model.

2. Estimation method according to claim 1, characterized:
in that in the 100% saturated operation substate, the adaptation is made on the state of charge of the battery and on the component corresponding to the polarization of the battery,
in that, in the close to 100% saturated operation substate, the adaptation is made on the component corresponding to the polarization of the battery,
in that, in the normal operation substate, the adaptation is made on the state of charge of the battery and on the component corresponding to the polarization of the battery,
in that, in the close to 0% charged operation substate, the adaptation is made on the component corresponding to the polarization of the battery, and
in that, in the 0% charged operation substate, the adaptation is made on the state of charge of the battery and on the component corresponding to the polarization of the battery.

3. Estimation method according to claim 1, characterized in that the state of operation of the battery in open circuit corresponds to operation substates chosen from the set comprising 100% saturated operation, close to 100% saturated operation, close to 0% charged operation, 0% charged operation, operation with a stable voltage, operation with an unstable voltage and operation in open circuit with a long stability.

4. Estimation method according to claim 3, characterized:
in that, in the 100% saturated operation, close to 100% saturated operation, close to 0% charged operation and 0% charged operation substates, the adaptation is made on the state of charge of the battery and on the component corresponding to the polarization of the battery,
in that, in the operating state with a stable voltage, the adaptation is made on the state of charge of the battery and on the component corresponding to the polarization of the battery with a preponderant adaptation on the state of charge,
in that, in the state of operation with an unstable voltage, the adaptation is made on the state of charge of the battery and on the component corresponding to the polarization of the battery with a preponderant adaptation on the component corresponding to the polarization, and
in that, in the state of operation in open circuit with a long stability, the adaptation is made only on the state of charge of the battery.

5. Estimation method according to claim 1, characterized in that a timer is used when the battery operates in open circuit in order to measure the time elapsed since the opening of the circuit.

6. Computer program stored on a data medium, said program comprising instructions allowing the use of an estimation method according to claim 1, when this program is loaded and run by an information technology system.

7. Information technology system such as, for example, a computer designed to be installed on board a motor vehicle, characterized in that it comprises means appropriate for applying a method according to claim 1.

8. Estimation method according to claim 2, characterized in that a timer is used when the battery operates in open circuit in order to measure the time elapsed since the opening of the circuit.

9. Estimation method according to claim 3, characterized in that a timer is used when the battery operates in open circuit in order to measure the time elapsed since the opening of the circuit.

10. Estimation method according to claim 4, characterized in that a timer is used when the battery operates in open circuit in order to measure the time elapsed since the opening of the circuit.

11. Computer program stored on a data medium, said program comprising instructions allowing the use of an estimation method according to claim 2, when this program is loaded and run by an information technology system.

12. Computer program stored on a data medium, said program comprising instructions allowing the use of an estimation method according to claim 3, when this program is loaded and run by an information technology system.

13. Computer program stored on a data medium, said program comprising instructions allowing the use of an estimation method according to claim 4, when this program is loaded and run by an information technology system.

14. Computer program stored on a data medium, said program comprising instructions allowing the use of an estimation method according to claim 5, when this program is loaded and run by an information technology system.

15. Information technology system such as, for example, a computer designed to be installed on board a motor vehicle, characterized in that it comprises means appropriate for applying a method according to claim 2.

16. Information technology system such as, for example, a computer designed to be installed on board a motor vehicle, characterized in that it comprises means appropriate for applying a method according to claim 3.

17. Information technology system such as, for example, a computer designed to be installed on board a motor vehicle, characterized in that it comprises means appropriate for applying a method according to claim 4.

18. Information technology system such as, for example, a computer designed to be installed on board a motor vehicle, characterized in that it comprises means appropriate for applying a method according to claim 5.

19. Computer program stored on a data medium, said program comprising instructions allowing the use of an estimation method according to claim 8, when this program is loaded and run by an information technology system.

20. Computer program stored on a data medium, said program comprising instructions allowing the use of an estimation method according to claim 9, when this program is loaded and run by an information technology system.
